(19) United States
(12) Patent Application Publication
(10) Pub. No.: US 2025/0185371 A1
(43) Pub. Date: Jun. 5, 2025

(54) TRANSPARENT DISPLAY APPARATUS

(71) Applicant: AUO Corporation, Hsinchu City (TW)

(72) Inventor: Cheng-Kuang Wang, Hsinchu City (TW)

(73) Assignee: AUO Corporation, Hsinchu City (TW)

(21) Appl. No.: 18/912,579

(22) Filed: Oct. 10, 2024

(30) Foreign Application Priority Data
Dec. 4, 2023 (TW) 112146993

(51) Int. Cl. H01L 27/12; H01L 25/16

(52) U.S. Cl. CPC H10D 86/60; H01L 25/167; H10D 86/441

(57) ABSTRACT

A transparent display apparatus includes pixel structures, first signal lines and second signal lines. Each of the pixel structures includes sub-pixel driving circuits and a light-emitting element group electrically connected to the sub-pixel driving circuits. The first signal lines and the second signal lines cross with each other to divide a first quadrant, a second quadrant, a third quadrant and a fourth quadrant. The pixel structures include two pixel structures respectively located in the first quadrant and the second quadrant or respectively located in the first quadrant and the fourth quadrant. Sub-pixel driving circuits of the two pixel structure are concentrated toward an intersection of the first signal lines and the second signal lines. The sub-pixel driving circuits of the two pixel structure are electrically connected to the same first signal line.

### CROSS-REFERENCE TO RELATED APPLICATION

This application claims the priority benefit of Taiwan application serial no. 112146993, filed on Dec. 4, 2023. The entirety of the above-mentioned patent application is hereby incorporated by reference herein and made a part of this specification.

### BACKGROUND

### Technical Field

The disclosure relates to a display apparatus, and in particular to a transparent display apparatus.

### Description of Related Art

A transparent display apparatus refers to a display apparatus that can provide a transparent display state for users to view the scene behind it. It is commonly found in shop windows, vending machines, etc. The transparent display apparatus has a display area and a transparent area, wherein the display area can provide a display image for the user to view, and the transparent area is transparent so that the user can view the rear scene. Pixels are provided in the display area to emit image beams toward a display surface of the transparent display apparatus to provide images. However, when the resolution of the transparent display apparatus is higher, the number of light-transmitting openings of the transparent display apparatus also increases, and an area of each of the light-transmitting openings also decreases, thereby affecting the visual effect of the background image.

### SUMMARY

The disclosure provides a transparent display apparatus with good visual effects on the background image.

A transparent display apparatus of the disclosure includes a plurality of pixel structures, a plurality of first signal lines and a plurality of second signal lines. Each of the pixel structures comprises a plurality of sub-pixel structures. Each of the sub-pixel structures comprises a sub-pixel driving circuit and a light-emitting element electrically connected to the sub-pixel driving circuit. Light-emitting elements of the sub-pixel structures form a light-emitting element group. The light-emitting element group comprises a first light-emitting element emitting first color light, a second light-emitting element emitting second color light and a third light-emitting element emitting third color light. The first signal lines and the second signal lines are electrically connected to the pixel structures. The first signal lines and the second signal lines cross each other to divide a first quadrant, a second quadrant, a third quadrant and a fourth quadrant. The first signal lines have a first side and a second side opposite each other. The second signal lines have a first side and a second side opposite each other. The first quadrant is located on the first side of the first signal lines and the first side of the second signal lines. The second quadrant is located on the first side of the first signal lines and the second side of the second signal lines. The third quadrant is located on the second side of the first signal lines and the second side of the second signal lines. The fourth quadrant is located on the second side of the first signal lines and the first side of the second signal lines. The pixel structures comprise two pixel structures located respectively at the first quadrant and the second quadrant or respectively at the first quadrant and the fourth quadrant. The sub-pixel driving circuits of the two pixel structures are concentrated toward a crossing point of the first signal lines and the second signal lines. The sub-pixel driving circuits of the two pixel structures are electrically connected to a single first signal line of the first signal lines.

### BRIEF DESCRIPTION OF THE DRAWINGS

FIG. 1 is a schematic top view of a transparent display apparatus according to the first embodiment of the present disclosure.

FIG. 2 is a schematic top view of a repeating unit of the transparent display apparatus according to the first embodiment of the present disclosure.

FIG. 3 is a schematic circuit diagram of a repeating unit of the transparent display apparatus according to the first embodiment of the present disclosure.

FIG. 4 is a schematic circuit diagram of a sub-pixel driving circuit of the transparent display apparatus of the first embodiment of this disclosure.

FIG. 5 is a schematic top view of the transparent display apparatus of the second embodiment of the present disclosure.

FIG. 6 is a schematic top view of a repeating unit of the transparent display apparatus according to the second embodiment of the present disclosure.

FIG. 7 is a circuit schematic diagram of a repeating unit of the transparent display apparatus of the second embodiment of the present disclosure.

FIG. 8 is a schematic top view of a transparent display apparatus according to the third embodiment of the present disclosure.

FIG. 9 is a schematic top view of a repeating unit of the transparent display apparatus according to the third embodiment of the present disclosure.

FIG. 10 is a circuit schematic diagram of a repeating unit of the transparent display apparatus of the third embodiment of the present disclosure.

FIG. 11 is a schematic top view of a transparent display apparatus according to the fourth embodiment of the present disclosure.

FIG. 12 is a schematic top view of a repeating unit of the transparent display apparatus according to the fourth embodiment of the present disclosure.

FIG. 13 is a circuit schematic diagram of a repeating unit of the transparent display apparatus of the fourth embodiment of the present disclosure.

FIG. 14 is a schematic top view of the transparent display apparatus of the fifth embodiment of the present disclosure.

FIG. 15 is a schematic top view of a repeating unit of the transparent display apparatus according to the fifth embodiment of the present disclosure.

FIG. 16 is a circuit schematic diagram of a repeating unit of the transparent display apparatus of the fifth embodiment of the present disclosure.

FIG. 17 is a schematic top view of a transparent display apparatus according to the sixth embodiment of the present disclosure.

FIG. 18 is a schematic top view of a repeating unit of the transparent display apparatus according to the sixth embodiment of the present disclosure.

FIG. 19 is a circuit schematic diagram of a repeating unit of the transparent display apparatus of the sixth embodiment of the present disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

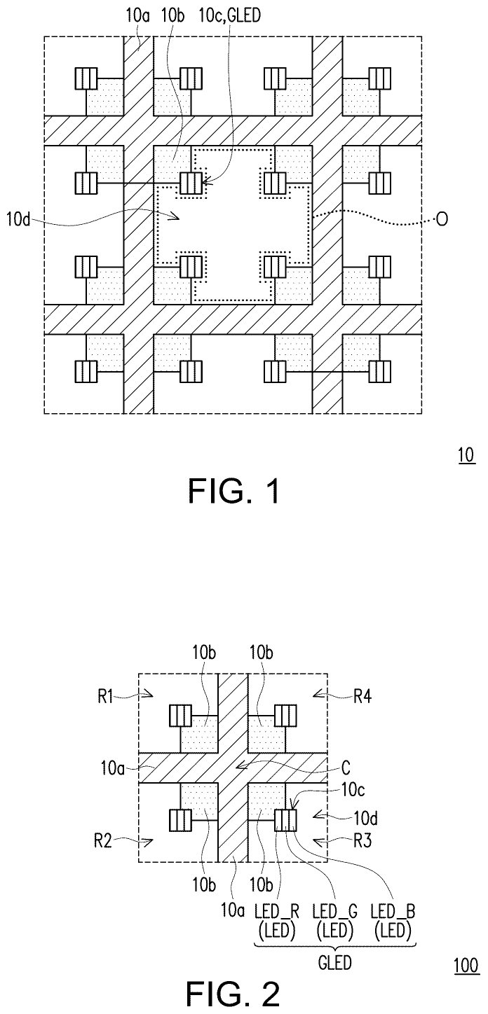

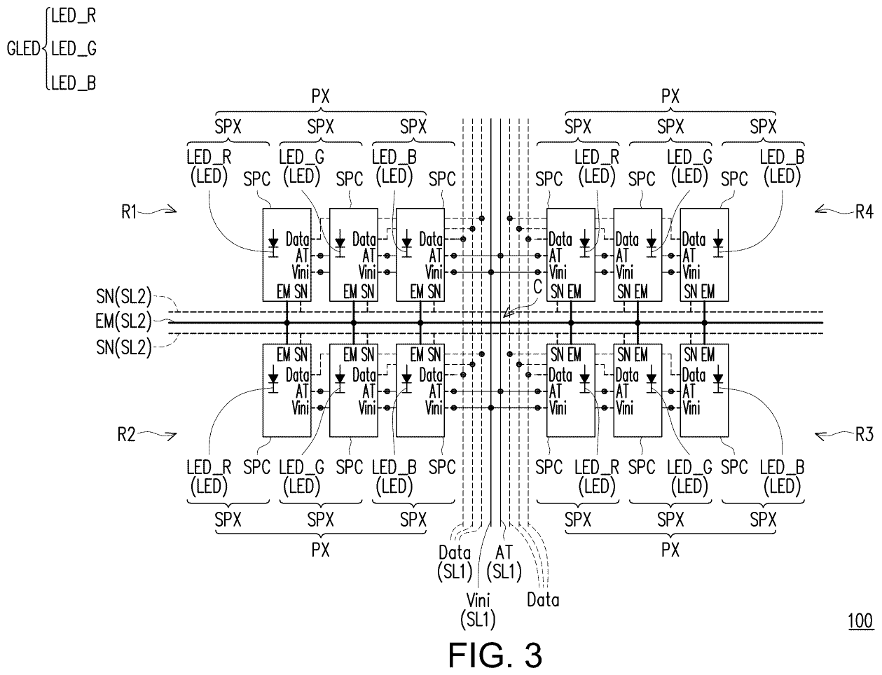

FIG. 1 is a schematic top view of a transparent display apparatus according to the first embodiment of the present disclosure. FIG. 2 is a schematic top view of a repeating unit of the transparent display apparatus according to the first embodiment of the present disclosure. FIG. 3 is a schematic circuit diagram of a repeating unit of the transparent display apparatus according to the first embodiment of the present disclosure.

Referring to FIGS. 1, 2 and 3, the transparent display apparatus 10 includes repeating units 100 arranged in an array. Each of the repeating unit 100 includes pixel structures PX, first signal lines SL1 and second signal lines SL2. The first signal lines SL1 and the second signal lines SL2 are electrically connected to the pixel structures PX and cross each other.

Each of the pixel structures PX includes sub-pixel structures SPX. Each of the sub-pixel structure SPX includes a sub-pixel driving circuit SPC and a light-emitting element LED electrically connected to the sub-pixel driving circuit SPC. Light-emitting elements LED of sub-pixel structures SPX of a single pixel structure PX form a light-emitting element group GLED. The light-emitting element group GLED includes a first light-emitting element LED_R emitting first color light, a second light-emitting element LED_G emitting second color light and third light-emitting element LED_B emitting a third color light. For example, in one embodiment, the first light-emitting element LED_R, the second light-emitting element LED_G and the third light-emitting element LED_B are micro light-emitting diodes (μLEDs) for emitting red light, green light and blue light respectively, but this disclosure is not limited to thereto.

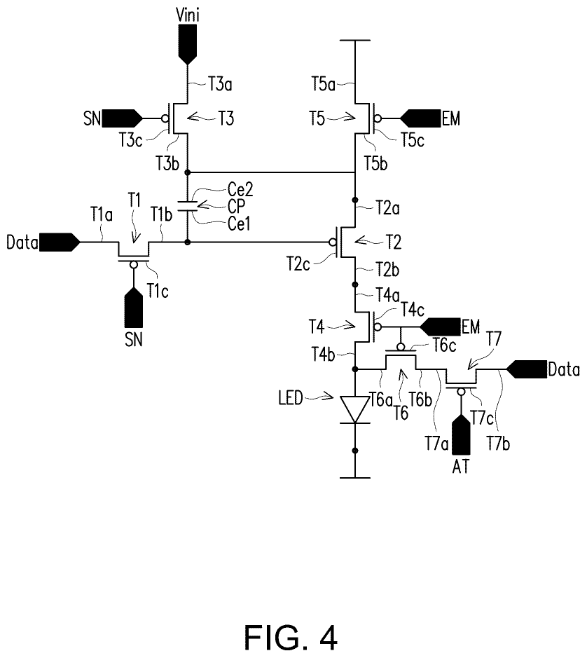

FIG. 4 is a schematic circuit diagram of a sub-pixel driving circuit of the transparent display apparatus of the first embodiment of this disclosure. Referring to FIG. 2, FIG. 3 and FIG. 4. For example, in one embodiment, the first signal lines SL1 include data lines Data, an initial signal line Vini and a detecting signal line AT. The second signal lines SL2 include at least one scan line SN and a transmitting signal line EM. Each of the sub-pixel driving circuit SPC includes a first transistor T1, a second transistor T2, a third transistor T3, a fourth transistor T4, a fifth transistor T5, a sixth transistor T6, a seventh transistor T7 and a capacitance CP. Each of the first transistor T1, the second transistor T2, the third transistor T3, the fourth transistor T4, the fifth transistor T5, the sixth transistor T6 and the seventh transistor T7 has a first terminal T1a\T2a\T3a\T4a\T5a\T6a\T7a, a second terminal T1b\T2b\T3b\T4b\T5b\T6b\T7b and a control terminal T1c\T2c\T3c\T4c\T5c\T6c\T7c, wherein the first terminal T1a of the first transistor T1 and the second terminal T7b of the seventh transistor T7 are electrically connected to a corresponding data line Data, the control terminal T1c of the first transistor T1 and the control terminal T3c of the third transistor T3 are electrically connected to a corresponding scan line SN, the second terminal T1b of the first transistor T1 and the control terminal T2c of the second transistor T2 are electrically connected to a first electrode Ce1 of the capacitance CP, the first terminal T3a of the third transistor T3 is electrically connected to the initial signal line Vini, the second terminal T3b of the third transistor T3 is electrically connected to a second electrode Ce2 of the capacitance CP, the first terminal T5a of the fifth transistor T5 is electrically connected to the power supply line (not shown), the control terminal T5c of the fifth transistor T5, the control terminal T4c of the fourth transistor T4 and the sixth transistor T6 of the control terminal T6c is electrically connected to the transmitting signal line EM, the second terminal T5b of the fifth transistor T5 is electrically connected to the second electrode Ce2 of the capacitance CP and the first terminal T2a of the second transistor T2, the second terminal T2b of the second transistor T2 is electrically connected to the first terminal T4a of the fourth transistor T4, the second terminal T4b of the fourth transistor T4 and the first terminal T6a of the sixth transistor T6 are electrically connected to a corresponding light-emitting element LED, the second terminal T6b of sixth transistor T6 is electrically connected to the first terminal T7a of the seventh transistor T7, and the control terminal T7c of the seventh transistor T7 are electrically connected to the detecting signal line AT. In short, in one embodiment, the sub-pixel driving circuit SPC may be a 7T1C architecture. However, this disclosure is not limited to thereto. In other embodiments, the sub-pixel driving circuit SPC may be a 1T1C architecture, a 2T1C architecture, a 3T1C architecture, a 3T2C architecture, a 4T1C architecture, a 4T2C architecture, or a 5T1C architecture., 5T2C architecture, 6T2C architecture, 7T2C architecture or any other possible architecture.

Referring to FIG. 1, FIG. 2 and FIG. 3, the first signal lines SL1 and the second signal lines SL2 are arranged in a first circuit area 10a of the transparent display apparatus 10, and the sub-pixel driving circuits SPC of each of the pixel structures PX are arranged in a second circuit area 10b, the light-emitting element group GLED of each of the pixel structures PX is arranged in a pixel area 10c of the transparent display apparatus 10. The area other than the first circuit area 10a, the second circuit area 10b and the pixel area 10c may be a transparent area 10d of the transparent display apparatus 10.

Referring to FIG. 2 and FIG. 3, the first signal lines SL1 and the second signal lines SL2 cross each other to divide a first quadrant R1, a second quadrant R2, a third quadrant R3 and a fourth quadrant R4. The first signal lines SL1 has a first side (for example: left side) and a second side (for example: right side) opposite each other. The second signal lines SL2 has a first side (for example: upper side) and a second side (for example: lower side) opposite each other. The first quadrant R1 is located on the first side of the first signal lines SL1 and the first side of the second signal lines SL2 (for example: the left side of the first signal lines SL1 and the upper side of the second signal lines SL2). The second quadrant R2 is located on the first side of the first signal lines SL2 and the second side of the second signal lines SL2 (for example: the left side of the first signal lines SL1 and the lower side of the second signal lines SL2). The third quadrant R3 is located on the second side of the first signal lines SL1 and the second side of the second signal lines SL2 (for example: the right side of the first signal lines SL1 and the lower side of the second signal lines SL2), and the fourth quadrant R4 is located on the second side of the first signal lines SL1 and the first side of the second signal lines SL2 (for example: the right side of the first signal lines SL1 and the upper side of the second signal lines SL2).

Referring to FIG. 2 and FIG. 3, it is worth noting that the pixel structures PX of each of the repeating units 100 includes two pixel structures PX located respectively in the first quadrant R1 and the second quadrant R2. The sub-pixel driving circuits SPC of the two pixel structures PX are concentrated toward a crossing point C of the first signal lines SL1 and the second signal lines SL2, and the sub-pixel driving circuits SPC of the two pixel structures PX are electrically connected to a single first signal line SL1. That is to say, in each of the repeating units 100, at least two second circuit areas 10b occupied by the sub-pixel driving circuits SPC of at least two adjacent pixel structures PX are concentrated toward the crossing point C, and at least two adjacent pixel structures PX share at least one first signal line SL1. Referring to FIGS. 1 and 2, in this way, transparent areas 10d of adjacent repeating units 100 can form a light-transmitting opening O of the transparent display apparatus 10 and an area of the light-transmitting opening O is large. Due to the large area of the light-transmitting opening O, the background image behind the transparent display apparatus 10 viewed through the light-transmitting opening O has high definition.

Referring to FIG. 2, FIG. 3 and FIG. 4, in one embodiment, first terminals T3a of first transistors T3 of the four pixel structures PX respectively located at the first quadrant R1, the second quadrant R2, the third quadrant R3 and the fourth quadrant R4 are electrically connected to a single first signal line SL1. In other words, at least two adjacent pixel structures PX share the single first signal line SL1, which helps to increase the aperture ratio and improve the visual effect of the background image. For example, in one embodiment, the first terminals T3a of the third transistors T3 of the four pixel structures PX respectively located at the first quadrant R1, the second quadrant R2, the third quadrant R3 and the fourth quadrant R4 may be electrically connected to a single initial signal line Vini.

Referring to FIG. 2, FIG. 3 and FIG. 4, in one embodiment, control terminals T7c of seventh transistors T7 of the four pixel structures PX respectively located at the first quadrant R1, the second quadrant R2, the third quadrant R3 and the fourth quadrant R4 are electrically connected to another first signal line SL1. For example, in one embodiment, the control terminals T7c of the of seventh transistors T7 of the four pixel structures PX respectively located at the first quadrant R1, the second quadrant R2, the third quadrant R3 and the fourth quadrant R4 are electrically connected to a single detecting signal line AT. That is to say, in one embodiment, the four pixel structures PX located respectively at the first quadrant R1, the second quadrant R2, the third quadrant R3 and the fourth quadrant R4 may share the single detecting signal line AT.

Referring to FIG. 2, FIG. 3 and FIG. 4, in one embodiment, sub-pixel driving circuits SPC of the four pixel structures PX respectively located at the first quadrant R1, the second quadrant R2, the third quadrant R3 and the fourth quadrant R4 are electrically connected to a single second signal line SL2. In one embodiment, the control terminals T4c of the fourth transistors T4, the control terminal T5c of the fifth transistors T5 and the control terminals T6c of the sixth transistors T6 of the four pixel structures PX respectively located at the first quadrant R1, the second quadrant R2, the third quadrant R3 and the fourth quadrant R4 are electrically connected to a single transmitting signal line EM. That is to say, in one embodiment, the four pixel structures PX located respectively at the first quadrant R1, the second quadrant R2, the third quadrant R3 and the fourth quadrant R4 may share the single transmitting signal line EM.

In the following embodiment, the reference numerals and part of the description of the foregoing embodiment are applied, where the same reference numerals are used to indicate the same or similar components, and descriptions of the same technical contents are omitted. Reference may be made to the foregoing embodiment for the omitted descriptions, which will not be repeated in following embodiment.

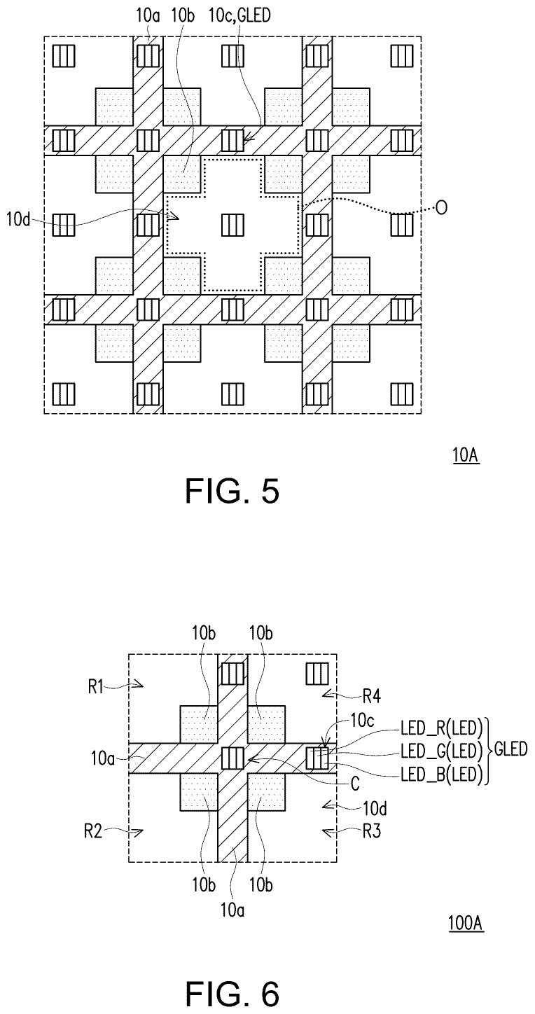

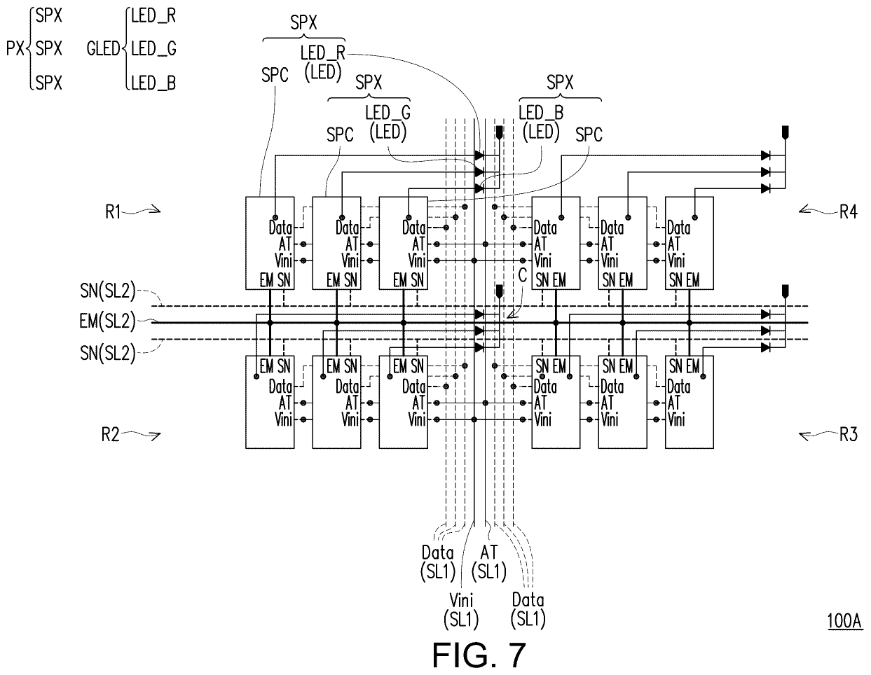

FIG. 5 is a schematic top view of the transparent display apparatus of the second embodiment of the present disclosure. FIG. 6 is a schematic top view of a repeating unit of the transparent display apparatus according to the second embodiment of the present disclosure. FIG. 7 is a circuit schematic diagram of a repeating unit of the transparent display apparatus of the second embodiment of the present disclosure.

The transparent display apparatus 10A and its repeating unit 100A of FIGS. 5, 6 and 7 are similar to the transparent display apparatus 10 and its repeating unit 100 of the aforementioned first embodiment. The difference between the two is that the positions of the multiple light-emitting element groups GLED of the multiple pixel structures PX are different. Specifically, in the embodiment of FIGS. 1, 2 and 3, the light-emitting element group GLED may be disposed at the corner of the second circuit area 10b; in the embodiment of FIGS. 5, 6 and 7, some light-emitting element groups GLED may be disposed on the first circuit area 10a, and other light-emitting element groups GLED may be surrounded by the transparent area 10d.

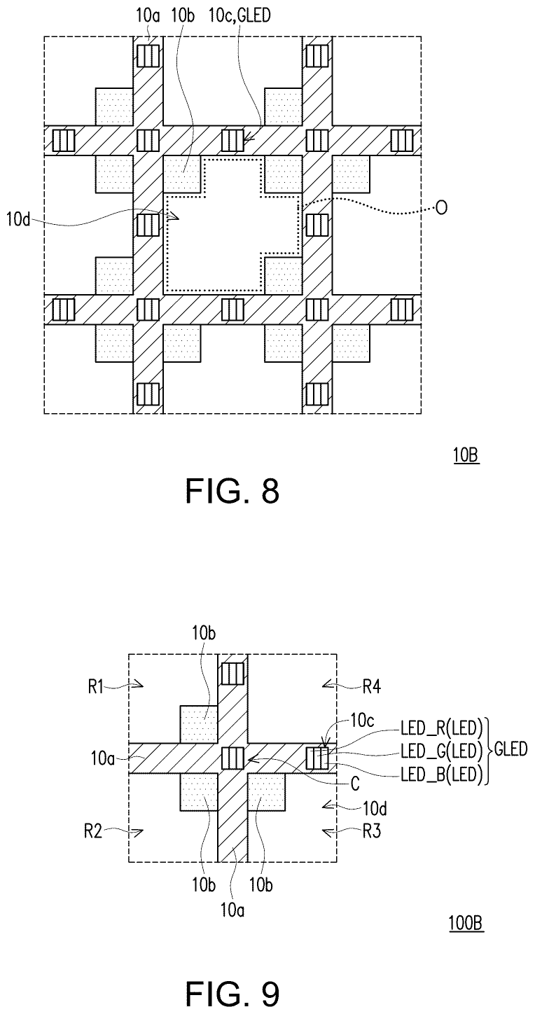

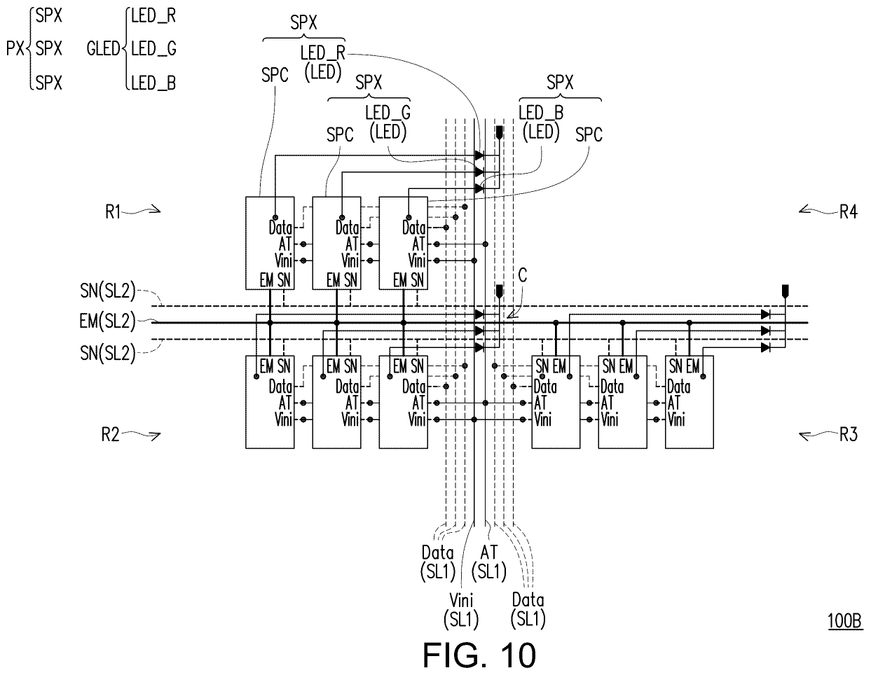

FIG. 8 is a schematic top view of a transparent display apparatus according to the third embodiment of the present disclosure. FIG. 9 is a schematic top view of a repeating unit of the transparent display apparatus according to the third embodiment of the present disclosure. FIG. 10 is a circuit schematic diagram of a repeating unit of the transparent display apparatus of the third embodiment of the present disclosure.

The transparent display apparatus 10B and its repeating unit 100B of FIGS. 8, 9 and 10 are similar to the transparent display apparatus 10 and its repeating unit 100 of the aforementioned first embodiment. The difference between the two is that: the positions of the light-emitting element groups GLED of the pixel structures PX are different. Specifically, in the embodiment of FIG. 8, FIG. 9 and FIG. 10, the light-emitting element group GLED may be disposed on the first circuit area 10a.

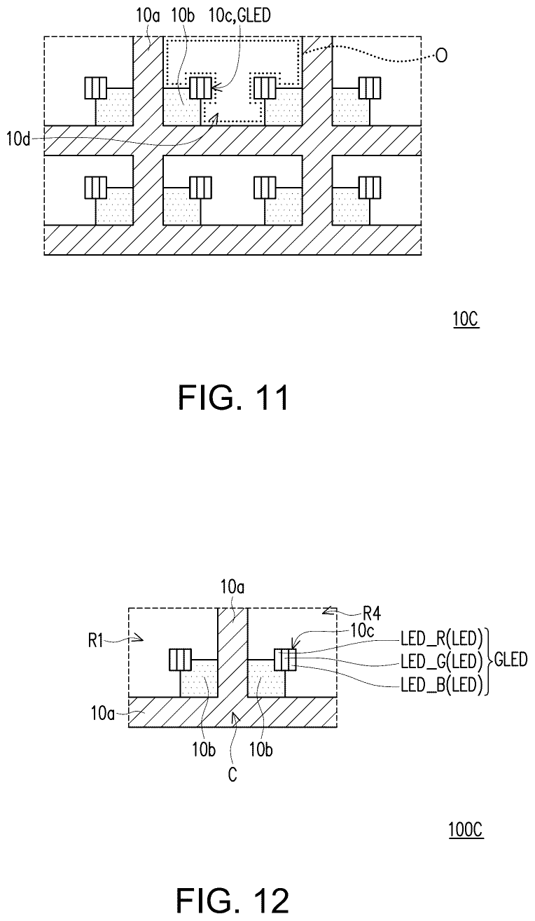

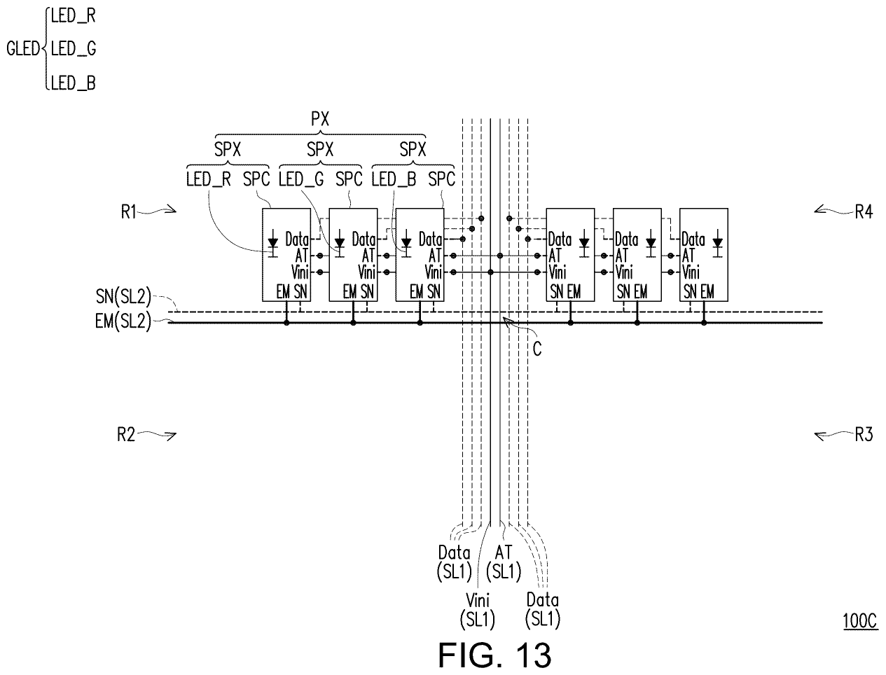

FIG. 11 is a schematic top view of a transparent display apparatus according to the fourth embodiment of the present disclosure. FIG. 12 is a schematic top view of a repeating unit of the transparent display apparatus according to the fourth embodiment of the present disclosure. FIG. 13 is a circuit schematic diagram of a repeating unit of the transparent display apparatus of the fourth embodiment of the present disclosure.

The transparent display apparatus 10C and its repeating unit 100C of FIGS. 11, 12 and 13 are similar to the transparent display apparatus 10 and its repeating unit 100 of the first embodiment. The difference between the two is that their repeating units 100 and 100C are different. Specifically, in the embodiments of FIGS. 11, 12 and 13, each of the repeating units 100 may include two pixel structures PX whose sub-pixel driving circuit SPC is disposed on the first quadrant R1 and the fourth quadrant R4.

Referring to FIGS. 11, 12 and 13, in this embodiment, the first terminals T3a (refer to FIG. 4) of the third transistors T3 of the two pixel structures PX respectively located at the first quadrant R1 and the fourth quadrant R4 are electrically connected to a single first signal line SL1 (for example: an initial signal line Vini). Control terminals T7c (please refer to FIG. 4) of the seventh transistor T7 of the two pixel structures PX respectively located at the first quadrant R1 and the fourth quadrant R4 are electrically connected to another first signal line SL1 (for example: a detecting signal line AT). Sub-pixel driving circuits SPC of the two pixel structures PX respectively located at the first quadrant R1 and the fourth quadrant R4 are electrically connected to a single second signal line SL2. Control terminals T4c (refer to FIG. 4) of the fourth transistors T4, control terminals T5c (refer to FIG. 4) of the fifth transistors T5 and control terminals T6c (please refer to FIG. 4) of the sixth transistor T6 of the two pixel structures PX respectively located at the first quadrant R1 and fourth quadrant R4 are electrically connected to a single second signal line SL2 (for example: a transmitting signal line EM).

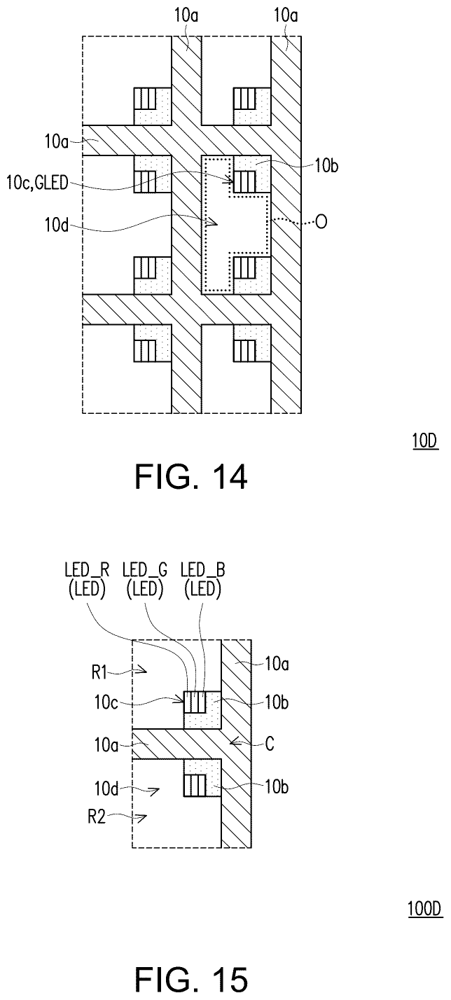

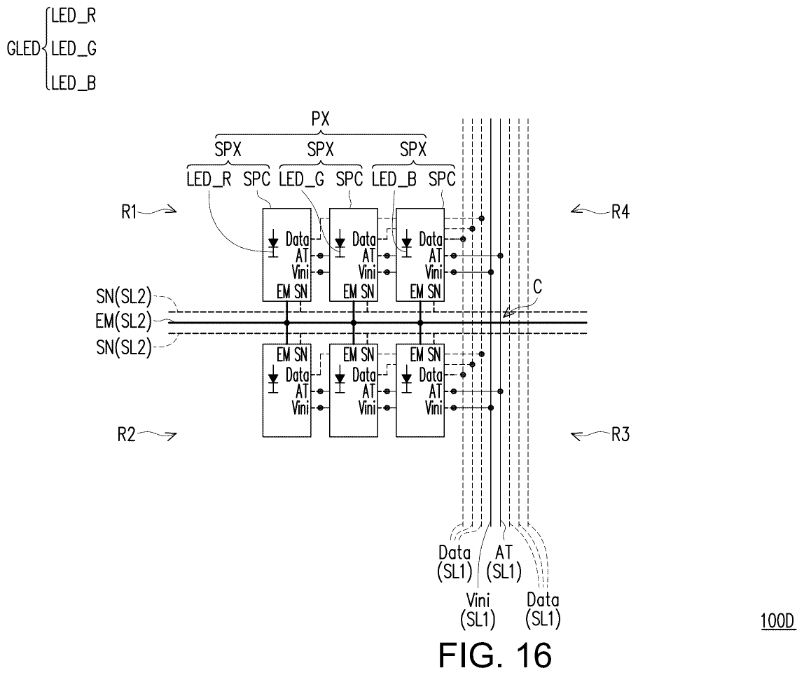

FIG. 14 is a schematic top view of the transparent display apparatus of the fifth embodiment of the present disclosure. FIG. 15 is a schematic top view of a repeating unit of the transparent display apparatus according to the fifth embodiment of the present disclosure. FIG. 16 is a circuit schematic diagram of a repeating unit of the transparent display apparatus of the fifth embodiment of the present disclosure.

The transparent display apparatus 10D and its repeating unit 100D of FIGS. 14, 15 and 16 are similar to the transparent display apparatus 10 and its repeating unit 100 of the aforementioned first embodiment. The difference between the two is that their repeating units 100 and 100D are different. Specifically, in the embodiment of FIGS. 14, 15 and 16, each of the repeating units 100D may include two pixel structures PX whose sub-pixel driving circuits SPC is disposed on the first quadrant R1 and the second quadrant R2.

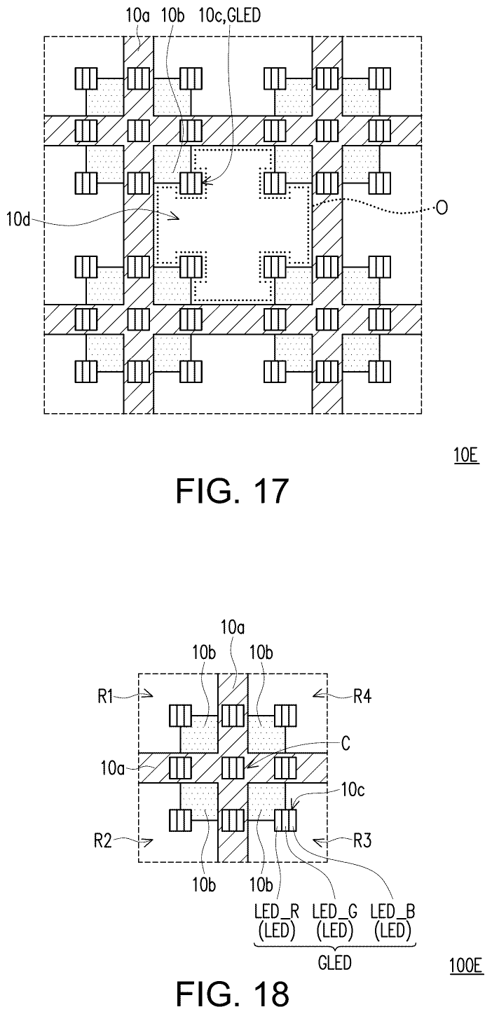

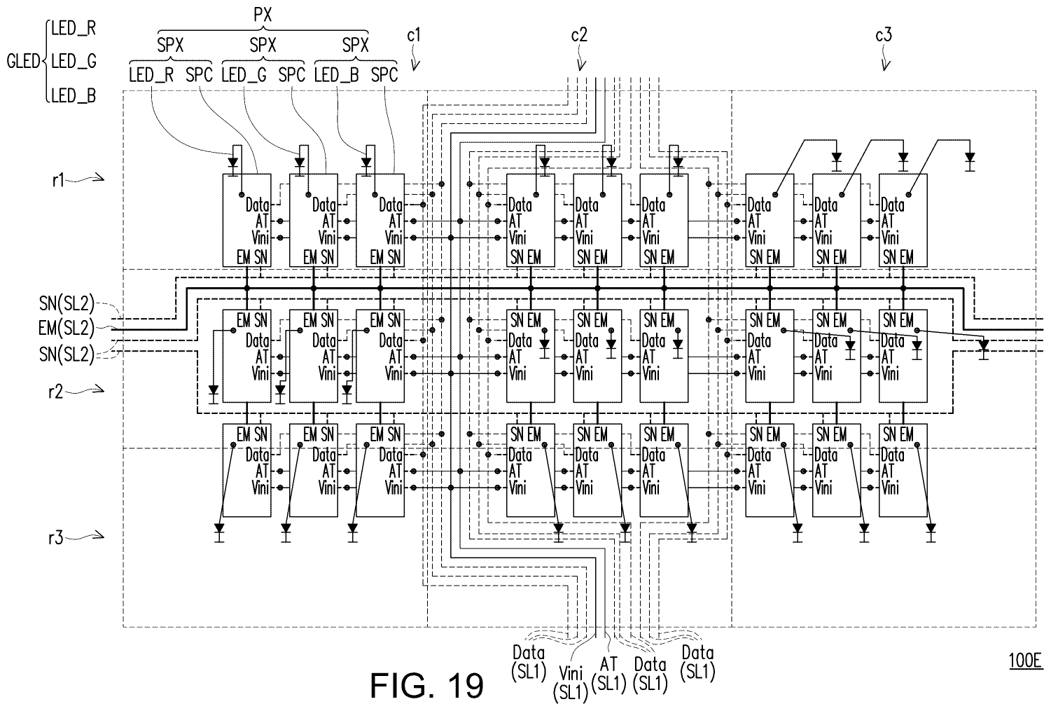

FIG. 17 is a schematic top view of a transparent display apparatus according to the sixth embodiment of the present disclosure. FIG. 18 is a schematic top view of a repeating unit of the transparent display apparatus according to the sixth embodiment of the present disclosure. FIG. 19 is a circuit schematic diagram of a repeating unit of the transparent display apparatus of the sixth embodiment of the present disclosure.

The transparent display apparatus 10E and its repeating unit 100E of FIGS. 17, 18 and 19 are similar to the transparent display apparatus 10 and its repeating unit 100 of the aforementioned first embodiment. The difference between the two is that their repeating units 100 and 100E are different. Specifically, in the embodiment of FIGS. 17, 18 and 19, each of repeating unit 100E may include light-emitting element groups GLED arranged in three rows and three columns.

Referring to FIGS. 18 and 19, in this embodiment, light-emitting element groups GLEDs of the pixel structures PX are arranged into three light-emitting element group columns c1, c2, and c3, the two light-emitting element group columns c1 and c3 of the three light-emitting element group lines c1, c2, and c3 are respectively located on the first side (for example: the left side) and the second side (for example: the right side) of the first signal lines SL1, sub-pixel driving circuits SPC electrically connected to the three light-emitting element group columns c1, c2, and c3 are electrically connected to a single first signal line SL1 (for example: an initial signal line Vini). In this embodiment, sub-pixel driving circuits SPC electrically connected to the three light-emitting element group columns c1, c2, and c3 are electrically connected to another first signal line SL1 (for example: a detecting signal line AT).

Referring to FIGS. 18 and 19, in this embodiment, light-emitting element groups GLED of the pixel structures PX are arranged into three light-emitting element group rows r1, r2, and r3. Two light-emitting element group rows r1 and r2 of the three light-emitting element group rows r1, r2 and r3 are respectively located on the first side (for example: the upper side) and the second side (for example: the lower side) of the second signal lines SL2. Sub-pixel driving circuits SPC electrically connected to the three light-emitting element group rows r1, r2, r3 are electrically connected to a single second signal line SL2 (for example: a transmitting signal line EM).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A transparent display apparatus comprising:
a plurality of pixel structures, wherein each of the pixel structures comprises a plurality of sub-pixel structures, each of the sub-pixel structures comprises a sub-pixel driving circuit and a light-emitting element electrically connected to the sub-pixel driving circuit, light-emitting elements of the sub-pixel structures form a light-emitting element group, the light-emitting element group comprises a first light-emitting element emitting first color light, a second light-emitting element emitting second color light and a third light-emitting element emitting third color light;
a plurality of first signal lines and a plurality of second signal lines electrically connected to the pixel structures, wherein the first signal lines and the second signal lines cross each other to divide a first quadrant, a second quadrant, a third quadrant and a fourth quadrant, and the first signal lines have a first side and a second side opposite each other, the second signal lines have a first side and a second side opposite each other, the first quadrant is located on the first side of the first signal lines and the first side of the second signal lines, the second quadrant is located on the first side of the first signal lines and the second side of the second signal lines, the third quadrant is located on the second side of the first signal lines and the second side of the second signal lines, and the fourth quadrant is located on the second side of the first signal lines and the first side of the second signal lines;
the pixel structures comprise two pixel structures located respectively at the first quadrant and the second quadrant or respectively at the first quadrant and the fourth quadrant, sub-pixel driving circuits of the two pixel structures are concentrated toward a crossing point of the first signal lines and the second signal lines, and the sub-pixel driving circuits of the two pixel structures are electrically connected to a single first signal line of the first signal lines.

2. The transparent display apparatus according to claim 1, wherein each of the sub-pixel driving circuit comprises a first transistor, a second transistor, a third transistor and a capacitance, and each of the first transistor, the second transistor and the third transistor has a first terminal, a second terminal and a control terminal, the second terminal of the first transistor and the control terminal of the second transistor are electrically connected to a first electrode of the capacitance, and the second terminal of the third transistor is electrically connected to a second electrode of the capacitance; first terminals of third transistors of the two pixel structures located respectively at the first quadrant and the second quadrant or respectively at the first quadrant and the fourth quadrant are electrically connected to the single first signal line of the first signal lines.

3. The transparent display apparatus according to claim 2, wherein each of the sub-pixel driving circuit further comprises a fourth transistor, a fifth transistor, a sixth transistor and a seventh transistor, each of the fourth transistor, the fifth transistor, the sixth transistor and the seventh transistor has a first terminal, a second terminal and a control terminal, the second terminal of the second transistor is electrically connected to the first terminal of the fourth transistor, the second terminal of the fifth transistor is electrically connected to the second electrode of the capacitance and the first terminal of the second transistor, the first terminal of the sixth transistor is electrically connected to the second terminal of the fourth transistor, and the first terminal of the seventh transistor is electrically connected to the second terminal of the sixth transistor; control terminals of seventh transistors of the two pixel structures respectively located at the first quadrant and the second quadrant or respectively located at the first quadrant and the fourth quadrant are electrically connected to another first signal line of the first signal lines.

4. The transparent display apparatus according to claim 1, wherein the sub-pixel driving circuits of the two pixel structures respectively located at the first quadrant and the second quadrant or respectively located at the first quadrant and the fourth quadrant are electrically connected to a single second signal line of the second signal lines.

5. The transparent display apparatus according to claim 4, wherein each of the sub-pixel driving circuit comprises a first transistor, a second transistor, a third transistor, a fourth transistor, a fifth transistor, a sixth transistor and a capacitance, each of the first transistor, the second transistor, the third transistor, the fourth transistor, the fifth transistor and the sixth transistor has a first terminal, a second terminal and a control terminal, the second terminal of the first transistor and the control terminal of the second transistor are electrically connected to a first electrode of the capacitance, the second terminal of the third transistor is electrically connected to a second electrode of the capacitance, the second terminal of the second transistor is electrically connected to the first terminal of the fourth transistor, the second terminal of the fifth transistor is electrically connected to the second electrode of the capacitance and the first terminal of the second transistor, and the first terminal of the sixth transistor is electrically connected to the second terminal of the fourth transistor; control terminals of fourth transistors, control terminals of fifth transistors and control terminals of sixth transistors of the two pixel structures respectively located at the first quadrant and the second quadrant or respectively located at the first quadrant and the fourth quadrant are electrically connected to the single second signal line.

6. The transparent display apparatus according to claim 1, wherein the pixel structures comprises four pixel structures respectively located at the first quadrant, the second quadrant, the third quadrant and the fourth quadrant, the sub-pixel driving circuits of the four pixel structures are concentrated toward the crossing point of the first signal lines and the second signal lines, and the sub-pixel driving circuits of the four pixel structures are electrically connected to the single first signal line.

7. The transparent display apparatus according to claim 6, wherein the sub-pixel driving circuits of the four pixel structures are electrically connected to a single second signal line of the second signal lines.

8. The transparent display apparatus according to claim 7, wherein the sub-pixel driving circuits of the four pixel structures are electrically connected to another first signal line of the first signal lines.

9. The transparent display apparatus according to claim 1, wherein light-emitting element groups of the pixel structures are arranged in at least three light-emitting element group columns, and two of the at least three light-emitting element group columns are respectively located on the first side and the second side of the first signal lines, and sub-pixel driving circuits electrically connected to the at least three light-emitting element group columns are electrically connected to the single first signal line.

10. The transparent display apparatus according to claim 9, wherein light-emitting element groups of the pixel structures are arranged in at least three light-emitting element group rows, two of the at least three light-emitting element group rows are respectively located on the first side and the second side of the second signal lines, and sub-pixel driving circuits electrically connected to the at least three light-emitting element group rows are electrically connected to a single second signal line of the second signal lines.
